(19) United States
(12) Patent Application Publication
(10) Pub. No.: US 2024/0070510 A1
(43) Pub. Date: Feb. 29, 2024

(54) SYSTEMS AND METHODS FOR CONTROLLING QUANTUM COMPONENTS

(71) Applicant: D-WAVE SYSTEMS INC., Burnaby (CA)

(72) Inventors: Min Jan Tsai, Richmond (CA); Colin C. Enderud, Vancouver (CA); Reza Molavi, North Vancouver (CA); Paul I. Bunyk, Pt. Roberts, WA (US)

(21) Appl. No.: 18/272,235

(22) PCT Filed: Jan. 11, 2022
(86) PCT No.: PCT/US2022/012000

§ 371 Date: Jul. 13, 2023

Related U.S. Application Data
(60) Provisional application No. 63/136,987, filed on Jan. 13, 2021.

(51) Int. Cl. G06N 10/40; H03M 1/66

(52) U.S. Cl. CPC G06N 10/40; H03M 1/66

(57) ABSTRACT

Programmable components of a quantum processor may be selectively programmed using digital to analog converters (DACs). A DAC with a first stage and a second stage and first and second quantum flux parametron (OFF) loops galvanically coupled to and extending from a respective one of the first stage and the second stage is discussed. The first stage has a first storage loop interrupted by a first Josephson junction and an interface for communicating with an external component. The second stage has a second storage loop interrupted by a second Josephson junction, the second storage loop galvanically coupled to the first storage loop, the first Josephson junction and the second Josephson junction coupled in series to a first control line. A method of loading flux quanta into targeted DAC stages is also discussed.

### FIELD

This disclosure generally relates to quantum computing, and particularly to the design and operation of components used for programming and operating other quantum components.

### BACKGROUND

### Quantum Computation

A quantum computer is a system that makes direct use of at least one quantum-mechanical phenomenon, such as superposition, tunneling, or entanglement, to perform operations on data. The elements of a quantum computer are quantum binary digits, known as qubits. One model of quantum computing is adiabatic quantum computing. Adiabatic quantum computing can be suitable for solving hard optimization problems, for example. Further details on adiabatic quantum computing systems, methods, and apparatus are described, for example, in U.S. Pat. Nos. 7,135,701 and 7,418,283.

### Quantum Annealing

Quantum annealing is a computational method that may be used to find a low-energy state of a system, typically preferably the ground state of the system. Similar in concept to classical simulated annealing, the method relies on the underlying principle that natural systems tend towards lower energy states because lower energy states are more stable. While classical annealing uses classical thermal fluctuations to guide a system to a low-energy state, quantum annealing may use quantum effects, such as quantum tunneling, as a source of delocalization to reach an energy minimum more accurately and/or more quickly than classical annealing. In quantum annealing, thermal effects and other noise may be present. The final low-energy state may not be the global energy minimum.

Adiabatic quantum computation may be considered a special case of quantum annealing. In adiabatic quantum computation, the system ideally begins and remains in its ground state throughout an adiabatic evolution. Thus, those of skill in the art will appreciate that quantum annealing systems and methods may generally be implemented on an adiabatic quantum computer. Throughout the present application, any reference to quantum annealing is intended to encompass adiabatic quantum computation unless the context requires otherwise.

### Quantum Components

Quantum components are structures in which quantum mechanical effects are observable. Quantum components may also be referred to as quantum devices. Quantum components include circuits in which current transport is dominated by quantum mechanical effects. Such components include spintronics, where electronic spin is used as a resource, and superconducting circuits. A superconducting circuit is a circuit that includes a superconducting device. A superconducting device is a device that includes a superconducting material. A superconducting material is a material that has no electrical resistance below critical levels of current, magnetic field, and temperature. Both spin and superconductivity are quantum mechanical phenomena. Quantum components can be used for measurement instruments, in computing machinery, and the like.

### Quantum Processor

A quantum processor may take the form of a superconducting quantum processor. A superconducting quantum processor may include a number of superconducting qubits and associated components that provide a local bias. A superconducting quantum processor may also include coupling devices (also known as couplers) that selectively provide communicative coupling between qubits.

A quantum processor can be a superconducting quantum processor that includes superconducting qubits. Wendin G. and Shumeiko V. S., “SUPERCONDUCTING QUANTUM CIRCUITS, QUBITS AND COMPUTING” (arXiv:cond-mat/0508729v1, 2005), provides an introduction to the physics and principles of operation of quantized superconducting electrical circuits for quantum information processing.

Superconducting qubits are solid state qubits based on circuits of superconducting materials. Operation of superconducting qubits is based on the underlying principles of magnetic flux quantization, and Josephson tunneling. Superconducting effects can be present in different configurations and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

In one implementation, a superconducting qubit includes a superconducting loop interrupted by a Josephson junction. The ratio of the inductance of the Josephson junction to the geometric inductance of the superconducting loop can be expressed as 2πLI_{C}/Φ₀ (where L is the geometric inductance, I_{C} is the critical current of the Josephson junction, and Φ₀ is the flux quantum). The inductance and the critical current can be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, a superconducting coupler includes a superconducting loop interrupted by a Josephson junction. The inductance and the critical current can be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further details and implementations of exemplary quantum processors that may be used in conjunction with the present systems and components are described in, for example, U.S. Pat. Nos. 7,533,068; 8,008,942; 8,195,596; 8,190,548; and 8,421,053.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

According to an aspect, there is provided a digital to analog converter (DAC) comprising a first stage comprising a first storage loop interrupted by a first Josephson junction, the first storage loop having an interface operable to communicate with an external component, a second stage comprising a second storage loop interrupted by a second Josephson junction, the second storage loop galvanically coupled to the first storage loop, the first Josephson junction and the second Josephson junction coupled in series to a first control line, and a first quantum flux parametron (QFP) loop and a second quantum QFP loop, the first and the second QFP loops galvanically coupled to and extending from a respective one of the first stage and the second stage.

According to other aspects the DAC may further comprise a third stage galvanically coupled to the second stage and a fourth stage galvanically coupled to the third stage, the third and fourth stages comprising a third storage loop and a fourth storage loop, the third and the fourth storage loops interrupted by a third Josephson junction and a fourth Josephson junction respectively, the third and the fourth Josephson junctions being coupled in series to the first control line and a third QFP loop and a fourth QFP loop, the third and the fourth QFP loops galvanically coupled to and extending from a respective one of the third stage and the fourth stage. Each QFP loop may comprise a respective Josephson junction, the respective Josephson junction of each QFP loop may comprise a respective compound Josephson junction, the first and second Josephson junctions may each comprise a compound Josephson junction, and the first and the second QFP loops may be symmetrically connected to the respective one of the first stage and the second stage, and the first QFP loop may be isolated from the second QFP loop. The first control line may bisect each of the first storage loop and the second storage loop, each of the first storage loop and the second storage loop may comprise a respective Josephson junction on each of a respective first side and a respective second side of each storage loop, and each of the first and the second QFP loops may be coupled to extend from the respective first side of the respective storage loop to the respective second side of the respective storage loop. Each of the first and the second QFP loops may be galvanically coupled to one or more additional QFP loops, the DAC may further comprise a second control line extending at least approximately perpendicularly to the first control line, and the second control line may be positioned to be inductively coupled to each of the first storage loop and the second storage loop, the first and the second QFP loops may be galvanically coupled along the first control line, the first, the second, the third, and the fourth QFP loops may be galvanically coupled along the first control line, the DAC may further comprise a flux bias line communicatively coupleable to the first QFP loop, the flux bias line may comprise a QFP stage of a QFP shift register, and the flux bias line may comprise a signal line.

According to an aspect, there is provided a method of selectively programming a programmable component of a quantum processor, the method comprising loading a first persistent current into a first digital to analog converter quantum flux parametron (DAC-QFP) loop, the first DAC-QFP loop galvanically coupled to a first digital to analog converter (DAC) storage loop, the first persistent current corresponding to an intended state of the first DAC storage loop, loading a second persistent current into a second DAC-QFP loop, the second DAC-QFP loop galvanically coupled to a second DAC storage loop, the second DAC storage loop galvanically coupled to the first DAC storage loop, the second persistent current corresponding to an intended state of the second DAC storage loop, applying a signal to one or more control lines in communication with the first DAC-QFP loop to introduce a first amount of flux into the first DAC storage loop based on the first persistent current of the first DAC-QFP loop via a first intervening Josephson junction, applying a signal to one or more control lines in communication with the second DAC-QFP loop to introduce a second amount of flux into the second DAC storage loop based on the second persistent current of the second DAC-QFP loop via a second intervening Josephson junction, and transferring a flux bias to the programmable component based on a combined flux comprising the first amount of flux within the first DAC storage loop and the second amount of flux within the second DAC storage loop through an interface carried by the first DAC storage loop that communicates with the programmable component.

According to other aspects, loading a first persistent current into a first DAC-QFP loop may comprise applying a current bias to a first quantum flux parametron (QFP) of a QFP shift register to provide a first current and shifting the first current through at least one first intervening QFP of the QFP shift register to reach the first DAC-QFP loop, loading a second persistent current into a second DAC-QFP loop may comprise applying a current bias to a second QFP of the QFP shift register that is electrically isolated from the first QFP of the QFP shift register to provide a second current and shifting the second current through at least one second intervening QFP of the QFP shift register to reach the second DAC-QFP loop, and loading a persistent current into a second QFP loop may comprise loading the second persistent current into the first QFP loop and shifting the second persistent current into the second QFP loop through one or more intermediate QFP loops, the intermediate QFP loop galvanically coupled to an intermediate DAC storage loop, wherein the first DAC storage loop, the intermediate DAC storage loop, and the second DAC storage loop are galvanically connected. Transferring a flux bias to the programmable component may comprise transferring a flux bias to one of a qubit, a coupler, a programming component, or a readout component.

According to an aspect, there is provided a quantum processor comprising one or more programmable superconducting components, a shift register comprising two or more rows extending in a first direction and formed from a plurality of quantum flux parametron (QFP) based shift register stages, each QFP based shift register stage within a respective row coupled to at least one other QFP based shift register stage of the plurality of QFP based shift register stages, a respective digital to analog converter quantum flux parametron (DAC-QFP) coupled to one QFP based shift register stage of each row in the shift register, a respective digital to analog converter (DAC) storage loop galvanically coupled to each DAC-QFP by a galvanic coupler, the galvanic coupler including a Josephson junction, each of the respective DAC storage loops being galvanically coupled along a second direction perpendicular to the first direction, and one of the respective DAC storage loops being in communication with one of the one or more programmable superconducting components.

According to other aspects, the DAC-QFPs may be arranged in an array, a power line may extend in the second direction between QFPs in a column extending along the first direction, a global signal line may extend perpendicular to the power line in the first direction and along a first row of QFPs, and the DAC storage loop may comprise a compound Josephson junction (CJJ) and the DAC-QFP may be galvanically coupled symmetrically to either side of the CJJ.

According to an aspect, there is provided a method of programming a target stage of a DAC comprising applying a bias current to a first QFP stage, shifting the bias current to a target QFP stage through an intermediate QFP stage, and applying current through one or more control lines to introduce flux into a target DAC storage loop.

According to other aspects, shifting the bias current to a target QFP stage through an intermediate QFP stage and applying current through one or more control lines to transfer flux into a target DAC storage loop may comprise applying a flux bias to a first Josephson junction carried by the first QFP stage, applying a flux bias to an intermediate Josephson junction carried by the intermediate QFP stage, suppressing the first Josephson junction of the first QFP stage, loading a pulse into the target DAC storage loop via the target QFP stage comprising, applying a flux bias to a target Josephson junction of the target QFP stage, introducing a current to a first control line in communication with the target DAC storage loop, introducing a current to a second control line in communication with a DAC Josephson junction to increase the current through the DAC Josephson junction over a threshold to cause the bias current to transfer from the target QFP stage into a galvanically coupled target DAC storage loop, removing the current from the first and second control lines, suppressing the flux bias of the target QFP stage, and iteratively loading flux into the target DAC storage loop via the target QFP stage until an intended number of flux quanta are introduced into the target DAC storage loop.

In other aspects, the features described above may be combined together in any reasonable combination as will be recognized by those skilled in the art.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements and may have been solely selected for ease of recognition in the drawings.

FIG. 1 is a schematic diagram of a hybrid computing system including a digital computer coupled to an analog computer, in accordance with the present systems, components, and methods.

FIG. 2 is a schematic diagram of a portion of an exemplary superconducting quantum processor.

FIG. 3 is a schematic diagram of an implementation of a digital to analog converter (DAC) having a single stage.

FIG. 4 is a schematic diagram of an implementation of a shift register and a DAC having three stages.

FIG. 5 is a schematic diagram of an implementation of a series of three DACs, each having four stages.

FIG. 6A is a schematic diagram of another implementation of a DAC having four stages.

FIG. 6B is a schematic diagram of an array of multiple DACs having four stages.

FIG. 7 is a flowchart of a method of selectively programming a programmable component of a quantum processor.

FIG. 8 is a flowchart of a method of programming a target stage of a DAC.

FIG. 9 is a representation of an example implementation of a quantum processor with an array of DACs programmed by a QFP shift register.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure, or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### Exemplary Computing System

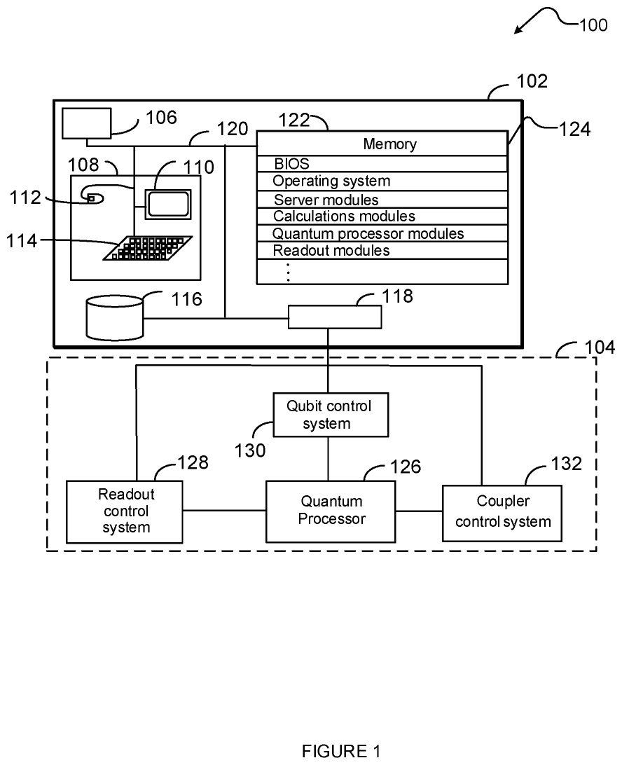

FIG. 1 illustrates a computing system 100 comprising a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store a set of modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, computing system 100 comprises an analog computer 104, which may include one or more quantum processors 126. Quantum processor 126 may include at least one superconducting integrated circuit using systems and methods described in the present application. Digital computer 102 may communicate with analog computer 104 via, for instance, a controller 118. Certain computations may be performed by analog computer 104 at the instruction of digital computer 102, as described in greater detail herein.

Digital computer 102 may include a user input/output subsystem 108. In some implementations, the user input/output subsystem includes one or more user input/output components such as a display 110, mouse 112, and/or keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer- or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) via system bus 120 and may include appropriate interfaces or controllers 118 coupled to system bus 120. Non-volatile memory 116 may serve as long-term storage for processor- or computer-readable instructions, data structures, or other data (sometimes called program modules) for digital computer 102.

Although digital computer 102 has been described as employing hard disks, optical disks and/or solid-state storage media, those skilled in the relevant art will appreciate that other types of nontransitory and non-volatile computer-readable media may be employed. Those skilled in the relevant art will appreciate that some computer architectures employ nontransitory volatile memory and nontransitory non-volatile memory. For example, data in volatile memory may be cached to non-volatile memory or a solid-state disk that employs integrated circuits to provide non-volatile memory.

Various processor- or computer-readable instructions, data structures, or other data may be stored in system memory 122. For example, system memory 122 may store instruction for communicating with remote clients and scheduling use of resources including resources on the digital computer 102 and analog computer 104. Also, for example, system memory 122 may store at least one of processor executable instructions or data that, when executed by at least one processor, causes the at least one processor to execute various algorithms and/or instructions. In some implementations system memory 122 may store processor- or computer-readable calculation instructions and/or data to perform pre-processing, co-processing, and post-processing to analog computer 104. System memory 122 may store a set of analog computer interface instructions to interact with analog computer 104.

Analog computer 104 may include at least one analog processor such as quantum processor 126. Analog computer 104 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1 K.

Analog computer 104 may include programmable elements such as qubits, couplers, and other components. Qubits may be read out via readout control system 128. Readout results may be sent to other computer- or processor-readable instructions of digital computer 102. Qubits may be controlled via a qubit control system 130. Qubit control system 130 may include on-chip Digital to Analog Converters (DACs) and analog lines that are operable to apply a bias to a target device. Couplers that couple qubits may be controlled via a coupler control system 132. Coupler control system 132 may include tuning elements such as on-chip DACs and analog lines. Qubit control system 130 and coupler control system 132 may be used to implement a quantum annealing schedule as described herein on analog processor 104. Programmable elements may be included in quantum processor 126 in the form of an integrated circuit. Qubits and couplers may be positioned in layers of the integrated circuit that comprise a first material. Other components, such as readout control system 128, may be positioned in other layers of the integrated circuit that comprise a second material.

### Superconducting Flux Storage Components

Superconducting flux storage components are also referred to in the present application as superconducting digital-to-analog converters (DACs) or flux DACs.

Quantum processors may have a plurality of programmable devices (also referred to herein as programmable components) for performing computations with quantum effects. Programmable devices may include qubits, couplers (which programmably couple qubits), and components thereof. Programmable devices are programmed via signals applied to influence their operation—for example, a biasing signal may be applied to a flux qubit to affect its flux during computation. On-chip control circuitry may be used to selectively apply static flux biases to superconducting loops in order to realize control parameters.

Such signals may require conversion and/or storage prior to being applied to programmable components. For example, a classical computer may generate digital signals for the quantum processor, and those digital signals may be converted to analog form via one or more digital-to-analog converters (DACs). The converted analog signal may be applied to the programmable component. As another example, a signal (which may be digital or analog) may be received by the quantum processor at one time before or during a computation and stored via a DAC until the signal is to be applied to a programmable component at a later time. DACs have many applications and may be used for one or more of these purposes (i.e., conversion and/or memory) and/or for other purposes. Examples of applications of DACs for these and other purposes are described in greater detail in, for example, U.S. Pat. Nos. 7,876,248 and 8,098,179.

Although the term DAC is used throughout, it will be understood that the described components may be used for a variety of purposes which are not necessarily restricted to converting digital signals to analog signals (and, in some implementations, do not involve such conversion at all). For example, as described above, superconducting DACs may be used by quantum processors to store a signal for a period of time (e.g., thereby operating as a form of memory).

### Quantum Flux Parametron

A quantum flux parametron (QFP) is a superconducting Josephson junction device similar in some respects to a compound RF-SQUID. A particular potential energy curve may be generated with a QFP device. This potential energy curve may resemble a “W” where the central peak or “barrier” is adjustable in height, as are the independent depths of the two wells on either side of the central barrier. Although the word “quantum” appears in the name of the QFP device, the device is generally operated in a classical manner. In short, quickly raising the height of the central barrier is classically believed to greatly disrupt the energy configuration of the system. QFP devices such as QFP shift registers are described further in U.S. Pat. No. 10,528,886.

### Exemplary Superconducting Quantum Processor

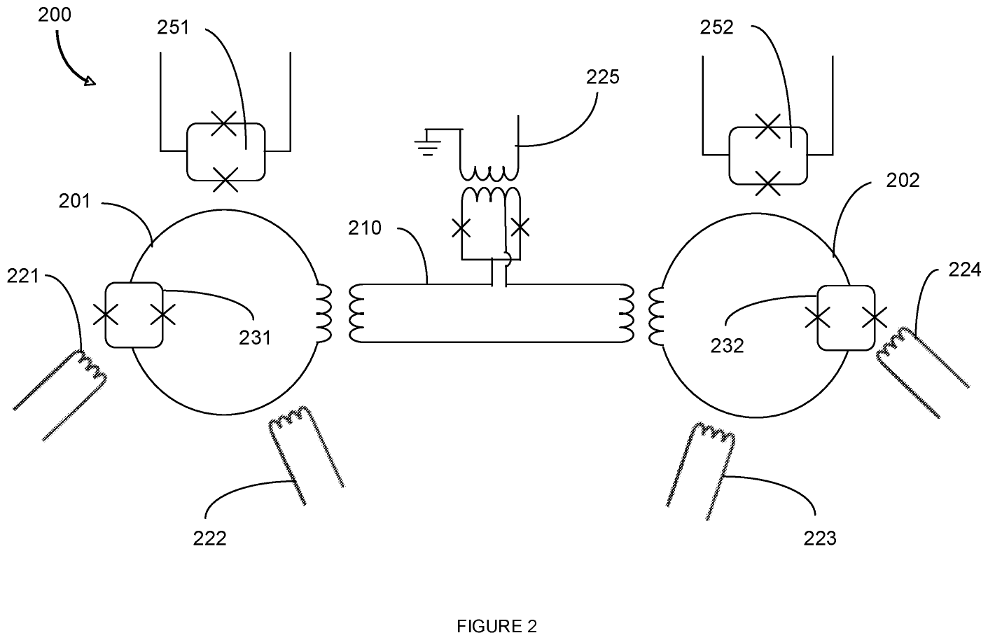

FIG. 2 is a schematic diagram of a portion of an exemplary superconducting quantum processor 200, according to at least one implementation. The portion of superconducting quantum processor 200 shown in FIG. 2 includes two superconducting qubits 201, and 202. Also shown is a tunable coupling (diagonal coupling) via coupler 210 between qubits 201 and 202 (i.e., providing 2-local interaction). While the portion of quantum processor 200 shown in FIG. 2 includes only two qubits 201, 202 and one coupler 210, those of skill in the art will appreciate that quantum processor 200 may include any number of qubits and any number of couplers coupling information between them.

Quantum processor 200 includes a plurality of interfaces 221-225 that are used to configure and control the state of quantum processor 200. Each of interfaces 221-225 may be realized by a respective inductive coupling structure, as illustrated, as part of a programming subsystem and/or an evolution subsystem. Alternatively, or in addition, interfaces 221-225 may be realized by galvanic coupling structures. As used herein, galvanic coupling refers to coupling achieved through one or more elements (e.g., a wire) that is physically shared between the coupled circuits. Galvanic coupling may also be referred to as a direct conductive connection. A direct conductive connection is formed between the circuits through the shared element, providing a direct electrical connection to couple the circuits. In contrast, inductive coupling refers to coupling achieved through interaction of magnetic field between the circuits without a direct electrical connection. A current through a portion of a first circuit creates a magnetic field around the first circuit, inducing a current in the second circuit. In some implementations, one or more of interfaces 221-225 may be driven by one or more DACs. Such a programming subsystem and/or evolution subsystem may be separate from quantum processor 200, or may be included locally (i.e., on-chip with quantum processor 200).

In the operation of quantum processor 200, interfaces 221 and 224 may each be used to couple a flux signal into a respective compound Josephson junction (CJJ) 231 and 232 of qubits 201 and 202, thereby realizing a tunable tunneling term in the system Hamiltonian. This coupling provides the off-diagonal σ^{x} terms of the Hamiltonian and these flux signals are examples of “delocalization signals”.

Similarly, interfaces 222 and 223 may each be used to apply a flux signal into a respective qubit loop of qubits 201 and 202, thereby realizing the hᵢ terms (dimensionless local fields for the qubits) in the system Hamiltonian. This coupling provides the diagonal σ^{z} terms in the system Hamiltonian. Furthermore, interface 225 may be used to couple a flux signal into coupler 210, thereby realizing the Jᵢⱼ term(s) (dimensionless local fields for the couplers) in the system Hamiltonian. This coupling provides the diagonal σᵢ^{z}σⱼ^{z} terms in the system Hamiltonian. Examples of Hamiltonians (and their terms) used in quantum computing are described in greater detail in, for example, US Publication No. 20140344322.

Throughout this specification and the appended claims, the term “quantum processor” is used to generally describe a collection of physical qubits (e.g., qubits 201 and 202) and couplers (e.g., coupler 210). The physical qubits 201 and 202 and the coupler 210 are referred to as the “programmable components” of the quantum processor 200 and their corresponding parameters (e.g., the qubit hᵢ values and the coupler Jᵢⱼ values) are referred to as the “programmable parameters” of the quantum processor. In the context of a quantum processor, the term “programming subsystem” is used to generally describe the interfaces (e.g., “programming interfaces” 222, 223, and 225) used to apply the programmable parameters to the programmable components of the quantum processor 200 and other associated control circuitry and/or instructions.

In order to control quantum devices (also referred to herein as programmable components) such as qubits 201, 202, and coupler 210 as described above, DACs may be used to couple flux into the respective device. These DACs may, in some implementations, be addressed or programmed using an XYZ scheme as described in U.S. Pat. No. 10,528,886. However, this type of programming requires lines that uniquely address each DAC and may result in a large number of lines being used. Managing these devices generally requires control over a number of parameters through communication with outside circuitry, that is, communication from outside the processor architecture. As processor sizes increase, providing sufficient control lines may become difficult. As such, it may be beneficial to provide DACs that can be programed using fewer lines.

As previously described, the programming interfaces of the programming subsystem may communicate with other subsystems which may be separate from the quantum processor or may be included locally on the processor. The programming subsystem may be configured to receive programming instructions in a machine language of the quantum processor and execute the programming instructions to program the programmable components in accordance with the programming instructions. Similarly, in the context of a quantum processor, the term “evolution subsystem” generally includes the interfaces (e.g., “evolution interfaces” 221 and 224) used to evolve the programmable components of the quantum processor 200 and other associated control circuitry and/or instructions. For example, the evolution subsystem may include annealing signal lines and their corresponding interfaces (221, 224) to the qubits (201, 202).

Quantum processor 200 also includes readout devices 251 and 252, where readout device 251 is associated with qubit 201 and readout device 252 is associated with qubit 202. In some implementations, such as shown in FIG. 2, each of readout devices 251 and 252 includes a direct current superconducting quantum interference device (DC-SQUID) inductively coupled to the corresponding qubit. In the context of quantum processor 200, the term “readout subsystem” is used to generally describe the readout devices 251, 252 used to read out the final states of the qubits (e.g., qubits 201 and 202) in the quantum processor to produce a bit string. The readout subsystem may also include other elements, such as routing circuitry (e.g., latching elements, a shift register, or a multiplexer circuit) and/or may be arranged in alternative arrangements (e.g., an XY-addressable array, an XYZ-addressable array, etc.), any of which may comprise DACs. Qubit readout may also be performed using alternative circuits, such as that described in PCT Patent Publication WO2012064974.

While FIG. 2 illustrates two physical qubits 201, 202, one coupler 210, and two readout devices 251, 252, a quantum processor (e.g., processor 200) may employ any number of qubits, couplers, and/or readout devices, including a larger number (e.g., hundreds, thousands or more) of qubits, couplers and/or readout devices. The application of the teachings herein to processors with a different (e.g., larger) number of computational components should be readily apparent to those of ordinary skill in the art.

Examples of superconducting qubits include superconducting flux qubits, superconducting charge qubits, and the like. In a superconducting flux qubit, the Josephson energy dominates or is equal to the charging energy. In a charge qubit the energy relationship is the reverse. Examples of flux qubits that may be used include radio frequency superconducting quantum interference devices (RF-SQUIDs), which include a superconducting loop interrupted by one Josephson junction, persistent current qubits, which include a superconducting loop interrupted by three Josephson junctions, and the like.

Programming interfaces such as 222, 223, and 225 of the example implementation of FIG. 2 may be connected to superconducting DACs. A superconducting DAC may act as a flux memory or flux storage device and can convert a digital amount of flux into flux stored in an analog device. In some implementations, a DAC includes a loop of material that is superconducting in a range of temperatures, the loop interrupted by one or more Josephson junctions. In one implementation, the DAC includes an RF-SQUID and includes a superconducting loop interrupted by a single Josephson junction. In another implementation, the DAC includes a superconducting loop interrupted by a compound Josephson junction (CJJ). The DAC CJJ can behave as a summing element for magnetic flux.

Storing flux in the DAC includes adding flux through the CJJ of the DAC into the storage loop of the DAC (i.e., into the superconducting loop of the DAC). Flux can be added to the storage loop of the superconducting DAC through the CJJ using one or more control signals or biases. Multiple flux quanta can be stored in a superconducting DAC implemented using a CJJ. See, for example, Johnson M. W. et al. “A scalable control system for a superconducting adiabatic quantum optimization processor”, arXiv:0907.3757v2, 24 Mar. 2010 for a description of flux DACs operable to control superconducting devices in an integrated circuit. Further details regarding implementations of programmable DACs can be found in U.S. patent application Ser. No. 16/098,801.

### Quantum Flux Parametron Digital to Analog Converters

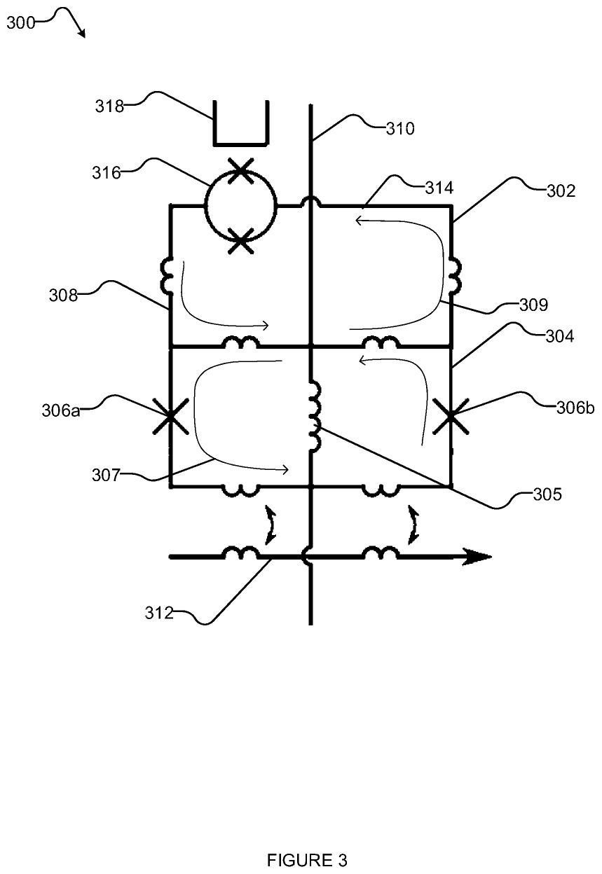

Referring to FIG. 3, a superconducting integrated circuit 300 is shown with one implementation of a digital to analog converter (DAC) 302. It will be understood that the material of superconducting integrated circuit 300 is generally a superconducting material, with a barrier material present in any Josephson junctions. Superconducting materials are generally superconductive below a critical temperature that is a characteristic of the given material. DAC 302 has a storage loop 304 galvanically coupled to a quantum flux parametron (QFP) loop 308. Storage loop 304 is shown with an example current path 307 and QFP loop 308 is shown with an example current path 309, for clarity and to aid in distinguishing the loops. It will be understood that these paths are added as an example only, and the current path may vary (e.g., be reversed, only occur in one of the loops at a given time). In the implementation of FIG. 3, storage loop 304 has a compound Josephson junction (CJJ) and a storage inductor 305. The CJJ is formed by first and second Josephson junctions 306a and 306b which interrupt loop 304. Circuit 300 has a first control line 310 intersecting storage loop 304, and a second control line 312 extending perpendicularly to first control line 310 that is inductively coupled to storage loop 304. It will be understood that, as used herein, “perpendicularly” refers to an angle that is approximately 90 degrees and may not be precisely 90 degrees. For example, in some implementations first control line 310 and second control line 312 may extend at an angle of 90 degrees±10 degrees relative to each other. It will also be understood that the perpendicular directions may be only in the region of circuit 300, and that the control lines may bend in different directions away from the region of circuit 300 and therefore no longer be perpendicular.

QFP loop 308 extends from storage loop 304 and has a body 314 interrupted by CJJ 316 that is coupled to a third control line 318. When a current is introduced by third control line 318 into CJJ 316, a flux quanta may be introduced into QFP loop 308. As used herein, CJJs generally include two electrically parallel current paths, each interrupted by a Josephson junction. First control line 310 and second control line 312 may then have current introduced to introduce flux into DAC storage loop 304 based on the current in QFP loop 308. This series of control pulses formed by current introduced into signal lines may be repeated in order to program a selected number of flux quanta into DAC storage loop 304. DAC storage loop 304 may be coupled to other DAC storage loops, may be coupled to a programmable component, and/or may be coupled to other DAC stages that are collectively coupled to a programmable component, as will be discussed further below. In the implementation shown in FIG. 3, QFP loop 308 is symmetrically connected to DAC storage loop 304. Control line 310 bisects storage loop 304 such that a Josephson junction 306a, 306b is found on either side of DAC storage loop 304 and QFP loop 308 extends from the first side of DAC storage loop 304 to the second side of DAC storage loop 304. This symmetrical connection between QFP loop 308 and DAC storage loop 304 may beneficially reduce or eliminate feedback current in QFP loop 308 due to flux quanta stored in DAC storage loop 304, increasing the programming range. In some implementations, the current flowing inside DAC storage loop 304 may be spread evenly through both sides of DAC storage loop 304. This arrangement may result in current communicating with QFP loop 308 being equal and opposite at either side of DAC storage loop 304. This equal and opposite current may therefore cancel any effect within QFP loop 308, resulting in little or no current being transferred back to QFP loop 308 as the amount of flux in DAC storage loop 304 increases.

Circuit 300 may be formed from a combination of low inductance materials and high inductance materials, as previously defined in more detail. In some implementations, QFP loop 308 and DAC storage loop 304 may be low inductance material, high inductance material, or a combination thereof. In some implementations, QFP loop 308 may be formed from primarily low inductance superconducting material, while DAC storage loop 304 may be formed from primarily high inductance superconducting material. In some implementations the low inductance superconducting material may be one of Ta, Nb, and Al, while the high inductance superconducting material may be one of WSi, MoN, NbN, NbTiN, TiN, and granular Aluminum.

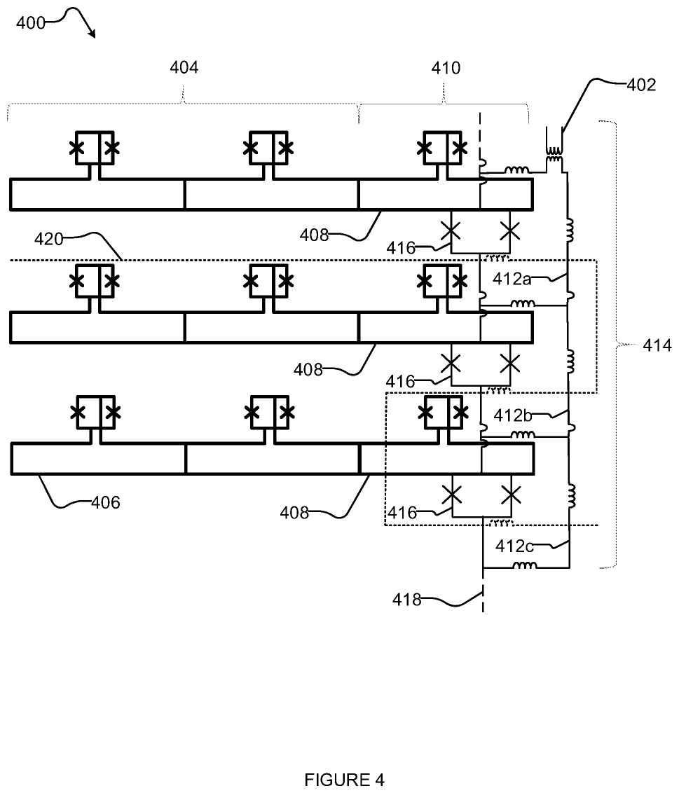

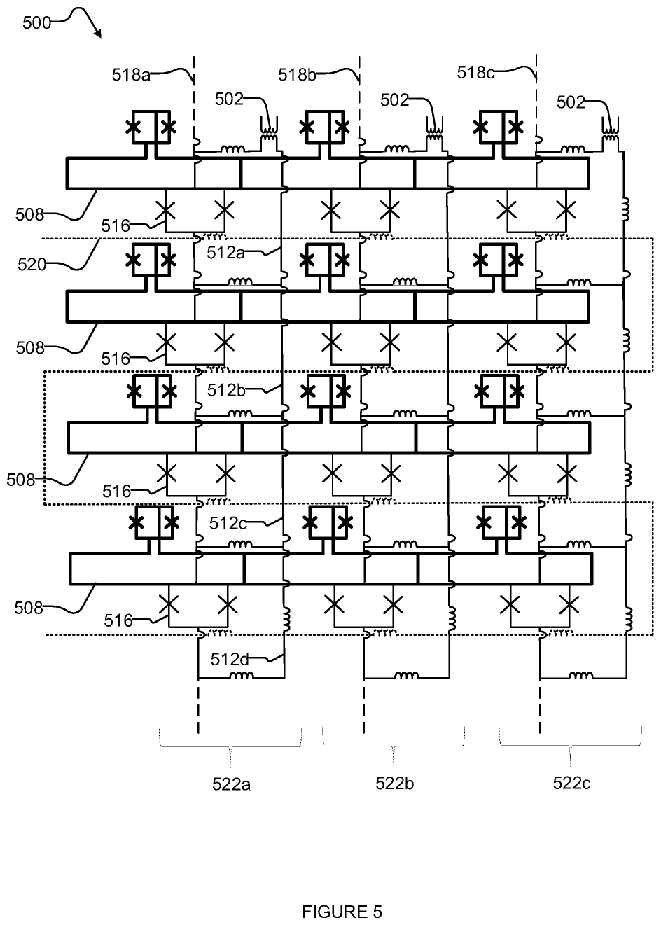

The example implementation of FIG. 4 shows a portion of a quantum processor 400. A programmable superconducting component 402, such as a qubit or coupler, is inductively coupled in order to be programmed. More than one superconducting component may be programmed, as will be discussed further with respect to FIG. 5. Quantum processor 400 has a shift register 404 with two or more rows formed from a plurality of QFP based shift register stages 406 (only one called out for clarity). Each QFP shift register stage 406 within a respective row is either magnetically or galvanically coupled to its neighbors and extends in a first direction. In each row of shift register 404, one QFP based shift register stage 406 has a respective neighboring DAC-QFP 408 of a multi-stage DAC 414 magnetically or galvanically coupled as shown in column 410. DAC-QFPs 408 are galvanically coupled to respective DAC storage loops 412 to form multi-stage DAC 414, the coupling between the DAC-QFP 408 and the DAC storage loop 412 including a Josephson junction 416. As shown, Josephson junction 416 may be a CJJ. Multi-stage DAC 414 has respective DAC storage loops 412a, 412b, 412c galvanically coupled along a second direction that is perpendicular to the first direction. As used herein, perpendicular refers to the general arrangement of rows of the QFP shift register 404 and the column of the multi-stage DAC 414, and does not necessarily refer to a precisely 90-degree angle. In some implementations, the angle of intersection may be 90 degrees+/−10 degrees. One of the DAC storage loops 412, in the implementation of FIG. 4 first storage loop 412a, is in communication with one of the one or more programmable superconducting components 402.

DAC-QFPs 408 may be used in combination with power line 418 (shown with a long dashed line for clarity) in communication with each DAC storage loop 412 and global signal line 420 (shown with a short dashed line for clarity) which extends along the row of QFPs 406. In some implementations DAC storage loops 412 have a CJJ 416, and power line 418 is in communication with CJJ 416. In some implementations, DAC-QFP 408 is coupled symmetrically to either side of CJJ 416. It will be understood that while three stages are shown in the implementation of FIG. 4, additional stages may be included for greater control precision when programming programmable component 402. The state passed to DAC-QFPs 408 will determine if the corresponding DAC storage loop 412 will be programmed with a flux quanta when global signal line 420 and power line 418 are raised. For example, in some implementations, when the flux bias provided by the DAC-QFP 408 of a respective stage has the same polarity as the flux from the global signal line, the DAC storage loop 412 will be programmed with a flux quanta when the control lines are raised. Conversely, if the DAC-QFP 408 is programmed with a flux bias having the opposite polarity, the DAC storage loop 412 will not be programmed when the signal lines are raised. In some implementations the direction of the current provided by the power line 418 may be used to determine if a positive or negative pulse will be stored in DAC storage loop 412 when the control lines are raised.

In some implementations, multi-stage DAC 414 may be programmed with a number of flux quanta provided to each DAC storage loop 412 to provide an intended value to be transmitted to programmable component 402. Once programmable component 402 has been programmed, it may be desired to reset multi-stage DAC 414. This may be done by unloading flux quanta from each DAC storage loop 412 by loading a number of pulses in the opposite direction of the loading pulse through switching the direction of the current provided by power line 418 and repeating a similar procedure to that described for programming multi-stage DAC 414. For example, where a stage of a DAC is loaded with a positive flux quanta, it may be unloaded with a negative pulse, and vice versa. In some implementations, such as in a four stage DAC, different stages of the DAC may be loaded with pulses in opposite directions (e.g., four stages loaded as (−4 +2 −1 0)), and may therefore be unloaded by pluses having the reverse direction of each stage. In other implementations, reset may be achieved by applying varying signals to global signal line 420 and/or power line 418.

As discussed above, circuit 400 may be formed from a combination of low inductance materials and high inductance materials. In some implementations, DAC-QFP 408 may be formed from primarily low inductance superconducting material, while DAC storage loop 412 may be formed from primarily high inductance superconducting material. In some implementations, the links connecting neighbouring QFP stages (e.g. 406 and 408) may be formed from high inductance materials. In some implementations the low inductance superconducting material may be one of Ta, Nb, and Al, while the high inductance superconducting material may be one of WSi, MoN, NbN, NbTiN, TiN, and granular Aluminum.

Referring to FIG. 5, an example implementation of a portion of a quantum processor 500 having an array of multi-stage DACs is shown. FIG. employs like numbers to those used in FIG. 4 (i.e., like in the two least significant digits), such that for example, programmable superconducting component 402 and programmable superconducting component 502 refer to similar devices. In the implementation of FIG. 5, QFP loops (referred to as DAC-QFPs) that are part of the QFP-DACs 508 described herein are arranged in an array as part of multiple multi-stage DACs and allow for programming of multiple programmable superconducting components 502. DAC-QFPs 508 may have one column that is magnetically or galvanically coupled to a shift register as described with respect to FIG. 4, or DAC-QFPs 508 may be addressed by addressing lines or other control schemes. Each respective DAC-QFP 508 is magnetically or galvanically coupled in a row to other DAC-QFPs 508, and each DAC-QFP 508 is also galvanically coupled to a respective DAC storage loop 512. The coupling between DAC-QFP 508 and DAC storage loop 512 includes a Josephson junction 516, which may be a CJJ. Respective DAC storage loops 512a, 512b, 512c, 512d are connected in a column to form four-stage DACs 522a, 522b, 522c (collectively 522) in communication with programmable component 502. For each section within the portion of a quantum processor 500, a DAC-QFP 508 is magnetically or galvanically connected in a first direction within a row of DAC-QFPs 508 and a DAC storage loop 512 is galvanically connected in a second direction within a column of DAC storage loops 512. The first and second direction are perpendicular, which, as discussed above, refers to an approximately 90-degree angle rather than requiring a precisely 90-degree angle. A programmable superconducting component 502 is connected to each column of DAC storage loops 512, which form a single four stage DAC 522 for programming programmable component 502. Power lines 518a, 518b, 518c (collectively 518, shown in long dashed lines for clarity) extend in the second direction in communication with each DAC storage loop 512 forming the four stage DAC 522, while global signal line 520 (shown in short dashed lines for clarity) extends perpendicular to power line 518 and is inductively connected to the CJJ of each DAC storage loop 512 in a given row. It will be understood that control line DAC storage loops 512 may be galvanically coupled along power line 518. It will further be understood that perpendicular as used herein refers to an approximately 90-degree angle rather than a precisely 90-degree angle as discussed above. It will also be understood that perpendicular refers to the portion of quantum processor 500 where power line 518 and global signal line 520 interact with DAC-QFP 508 and DAC storage loop 512, and that the control lines may bend in different directions away from this portion and may not be perpendicular in those regions. In the example implementation of FIG. 5, global signal line 520 is parallel with power line 518 at the edges of the circuit, where global signal line 520 bends to reverse direction along the next row. As shown, global signal line 520 may reverse direction to address all DAC storage loops 512 in the array. It will be understood that in some implementations more than one global signal line may be used to provide a global bias signal, while in other implementations a current provided by a single wire may provide a global flux bias signal to all of the DACs in an array. As used herein the terms “power line” and “global signal line” refer to control lines that introduce a current to the respective components in order to introduce flux quanta into DAC storage loops 512 when a respective DAC storage loop 512 is selected by the programming of the DAC-QFPs 508. As discussed above, circuit 500 may be formed from a combination of low inductance materials and high inductance materials. In some implementations it may be beneficial to have high inductance material in links between devices.

In some implementations DAC storage loops 512 have a CJJ 516, and DAC-QFP 508 is coupled symmetrically to either side of CJJ 516. As shown, the rows of DAC-QFPs 508 are electrically isolated from communication with one another and the columns of DAC storage loops 512 are electrically isolated from communication with one another. It will be understood that the portion of quantum processor 500 is not limited to the three columns of four stage DACs 522 shown in the implementation of FIG. 5, and each DAC-QFP 508 may have a galvanic coupling to one or more additional DAC-QFP loops, to a shift register, or to other devices. It will also be understood that in some implementations, while the columns of DAC storage loops 512 are not directly connected to each other, and therefore are considered to be electrically isolated from communication with one another, they may share power lines 518. For example, in one implementation, the portion of quantum processor 500 shown in FIG. 5 may be repeated multiple times within an array. Three DACs 522 may each be addressed with an independent power line 518a, 518b, 518c, and additional DACs 522 may be connected in parallel such that power line signals are applied through power line 518a to every third DAC 522a, power line signals are applied through power line 518b to every third DAC 522b connected at the next DAC-QFP in the array, and power line signals are applied through power line 518c to the remaining DACs 522c. It will be understood that different numbers of repeated power lines, referred to as “colors”, may be used in different implementations, such as four colors or five colors instead of the three colors described above. It will also be understood that similar addressing schemes may be applied to the other implementations described herein.

DAC programming may be achieved in a number of ways, such as XYZ addressing as discussed above. As processor sizes increase and the number of DACs to be controlled within the processor scales accordingly, the number of lines required for programming increases. It may be beneficial to introduce other programming schemes that require fewer control lines to allow for increases in device numbers. The DAC incorporating a QFP stage discussed herein may beneficially allow for DAC programming with fewer lines and may also beneficially allow for parallel programming of large numbers of DACs with few control lines.

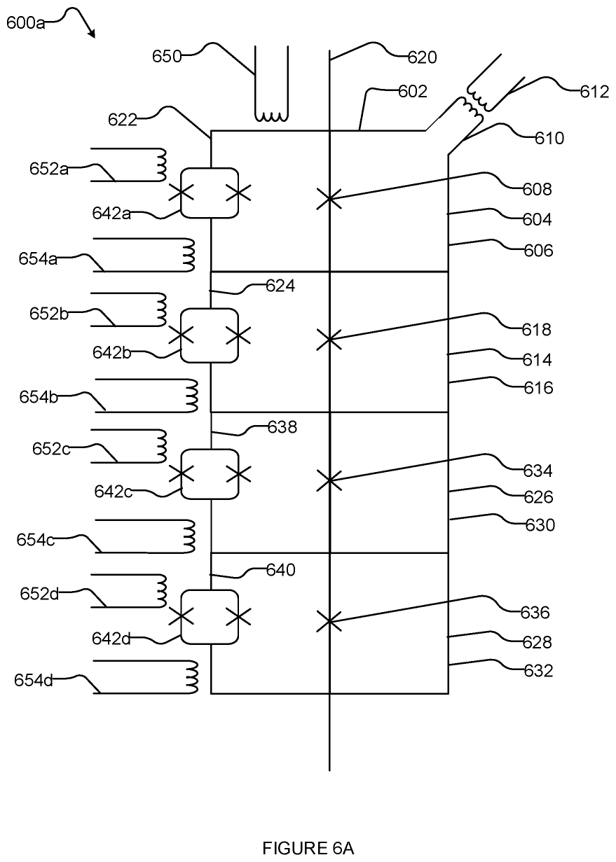

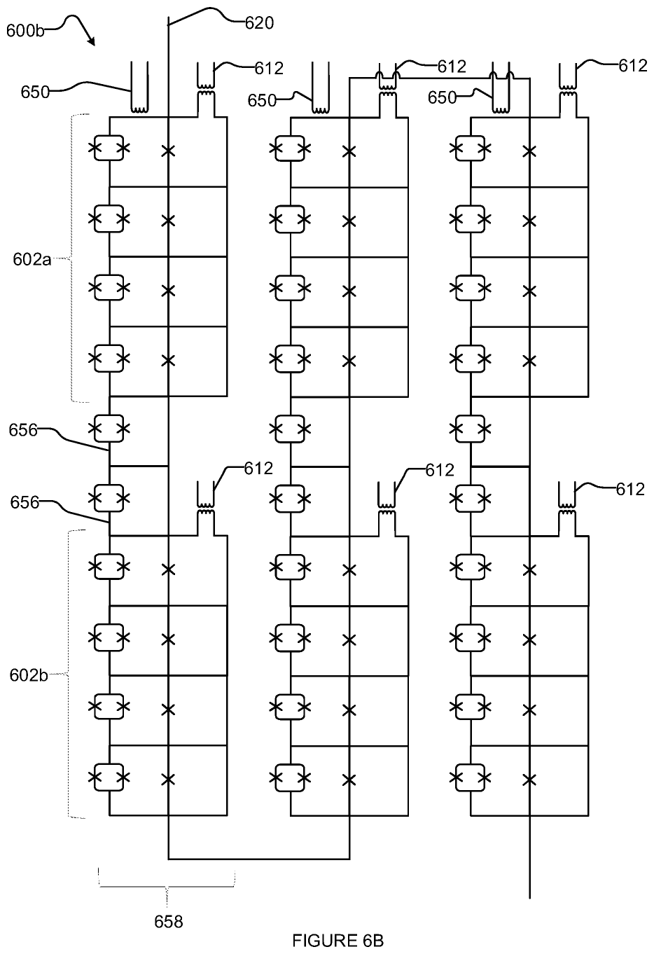

Referring to FIG. 6A, a superconducting integrated circuit 600a is shown with one implementation of a DAC 602. DAC 602 has a first stage 604 with a first storage loop 606 interrupted by a first Josephson junction 608. First storage loop 606 carries or has an interface 610 for communicating with an external component 612, which may be a programmable device such as a qubit or coupler. DAC 602 has a second stage 614 with a second storage loop 616 interrupted by a second Josephson junction 618. Second storage loop 616 is galvanically coupled to first storage loop 606. First Josephson junction 608 and second Josephson junction 618 are coupled in series to a first control line 620. Superconducting integrated circuit 600a further has first and second QFP loops 622 and 624 galvanically coupled to and extending from a respective one of first stage 604 and second stage 614. In some implementations, first and second Josephson junctions 608, 618 may be CJJs.

As show in FIG. 6A, in some implementations, a DAC may include a third stage 626 galvanically coupled to second stage 614 and a fourth stage 628 galvanically to third stage 626. Third and fourth stages 626, 628 have third and fourth storage loops 630, 632 interrupted by third and fourth Josephson junctions 634, 636 respectively, third and fourth Josephson junctions 634, 636 being coupled in series to first control line 620. Third and fourth stages 626, 628 also have third and fourth QFP loops 638, 640 galvanically coupled to and extending from a respective one of third stage 626 and fourth stage 628. In the implementation of FIG. 6A, each QFP loop 622, 624, 638, 640 has a Josephson junction, in this case a CJJ 642a, 642b, 642c, 642d.

While the example implementation of FIG. 6A is asymmetrical, it will be understood that a similar circuit may be designed with two CJJs for each stage that is more symmetrical. Additional control lines may be provided, such as flux bias line 650, Josephson junction annealing lines 652a, 652b, 652c, 652d, and trigger lines 654a, 654b, 654c, 654d. In some implementations QFP loops 622, 624, 638, and 640 may be formed from a low inductance superconducting material, while DAC storage loops 606, 616, 630, and 632 may be formed from a high inductance superconducting material. In some implementations the low inductance superconducting material may be one of Ta, Nb, and Al, while the high inductance superconducting material may be one of WSi, MoN, NbN, NbTiN, TiN, and granular Aluminum. In order to address a particular DAC stage (604, 614, 626, 628) the persistent current in the QFP loop (622) and the control lines in communication with the respective stage (for example, 654a, and 620 in communication with stage 604) and have current that adds constructively to load a flux quanta into the respective DAC storage loop (606).

In some implementations, such as in the example implementation of FIG. 6B, a superconducting integrated circuit 600b may include an array of DACs 602 in communication with multiple programmable components 612. In FIG. 6B, like numbers to those used in FIG. 6A indicate related components. In some implementations, multiple DACs 602 (two called out as 602a and 602b for clarity) may be spaced along first control line 620. Superconducting integrated circuit 600b may include intervening QFP stages 656. In the example implementation of FIG. 6B, superconducting integrated circuit 600b includes two intervening QFP stages 656 separating DACs 602a and 602b. Similar intervening QFP stages are found in each column 658 of DACs 602. In other implementations there may not be intervening QFP stages, or there may be a different number of QFP stages. In some implementations it may be beneficial to have an even number of intervening QFP stages 656 such that the direction of current flow is preserved as it is transferred between DACs 602. Each column 658 may have a single flux bias line 650 that transfers flux to be shifted into the QFP stages of DACs 602 and intervening QFP stages 656.

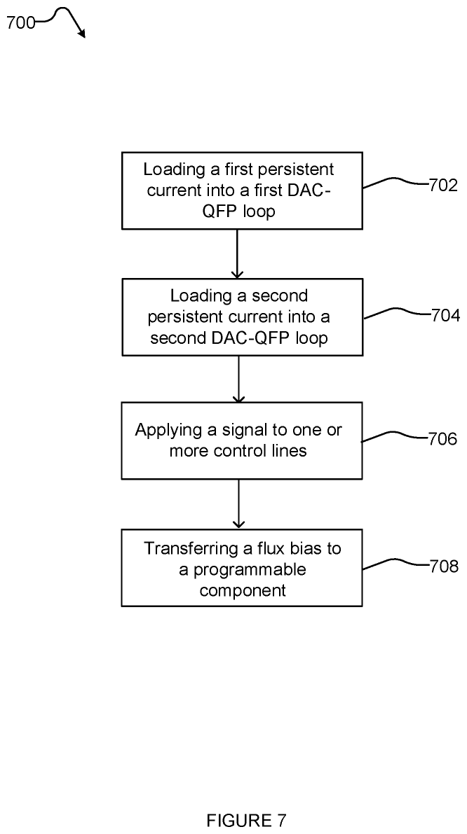

FIG. 7 is a flow chart illustrating an example method 700 for selectively programming a programmable component of a quantum processor according to the present disclosure. The programmable component may, for example, be one of a qubit, a coupler, a programming component such as a shift register or a separate DAC that communicates with a further programmable device, and a readout component such as a shift register or readout QFP that communicates with readout lines. Method 700 may be implemented by a programming system such as the system discussed with respect to FIG. 1.

Method 700 includes acts 702 to 708, and those of skill in the art will appreciate that in alternative implementations certain acts may be omitted and/or additional acts may be added. Those of skill in the art will appreciate that the illustrated order of the acts is shown for exemplary purposes only and may change in alterative implementations.

Method 700 starts, for example, in response to an initiation of the programming. At 702, a first persistent current is loaded into a first DAC-QFP loop that is galvanically coupled to a first DAC storage loop. Persistent current may be loaded by a flux bias line or signal line, or through a shift register as discussed above. The persistent current corresponds to an intended state (or number of flux quanta) of the first DAC storage loop after receiving the current loaded into the first DAC-QFP loop. For example, if it is desired to load a flux quanta into the respective DAC storage loop, the persistent current in the DAC-QFP loop may be in a first direction (for example, clockwise) while if it is not desired to load a flux quanta into the respective DAC storage loop, the persistent current in the DAC-QFP loop may be in a second direction (for example, counterclockwise).

At 704, a second persistent current is loaded into a second DAC-QFP loop. The second DAC-QFP loop is galvanically coupled to a second DAC storage loop, and the second DAC storage loop is galvanically coupled to the first DAC storage loop. As above, the second persistent current corresponds to an intended state of the second DAC storage loop.

In some implementations, where a QFP shift register is connected to the DAC-QFP loops (see FIG. 5 for one implementation), the first persistent current is loaded into the first DAC-QFP loop by applying a current bias to a first QFP of a QFP shift register and shifting the current through at least one first intervening QFP of the QFP shift register to reach the first DAC-QFP loop. The second persistent current is also loaded into the second DAC-QFP loop by applying a current bias to a second QFP of the QFP shift register. The second QFP of the QFP shift register is isolated from the first QFP of the QFP shift register and the current is shifted through at least one second intervening QFP of the QFP shift register to reach the second DAC-QFP loop. In some implementations loading a persistent current into the second QFP loop may involve loading the second persistent current into the first QFP loop and then shifting the second persistent current into the second QFP loop. This may be achieved through one or more intermediate QFP loops that are galvanically coupled to an intermediate storage loop, where the first storage loop, the intermediate storage loop, and the second storage loop are galvanically connected.

At 706, a signal is applied to one or more control lines in communication with the first DAC-QFP loop to shift an amount of flux into the first DAC storage loop based on the persistent current of the first DAC-QFP loop via a first intervening Josephson junction. For example, if the persistent current in the DAC-QFP loop was clockwise, the combined contribution of the DAC-QFP loop and the one or more control lines is sufficient to push flux through the JJ and introduce a flux quanta into the DAC storage loop. The power level required is selected to cause a flux quantum to be added into the intervening Josephson junction when an upper threshold is exceeded by combining the contributions of the DAC-QFP and the one or more control lines. As discussed above, in some implementations, this may be achieved by two control lines in communication with each stage.

In some implementations, the signal applied to the one or more control lines in communication with the first DAC-QFP loop also applies a signal to one or more control lines in communication with the second DAC-QFP loop to shift an amount of flux into the second DAC storage loop based on the persistent current of the second DAC-QFP loop via a second intervening Josephson junction. In other implementations, this signal may be applied in a separate act.

Loading one or more flux quanta into the DAC storage loop is also referred to in the present application as programming the DAC. Programming the DAC can also include removing one or more flux quanta from the DAC storage loop. In one implementation, removing one or more flux quanta from the DAC storage loop includes reversing a signal on an address line. It will be understood that programming may require both raising and lowering the signal on a control line such as an address line in order to cause a flux quantum to move into the DAC storage loop.

At 708, a flux bias is transferred to the programmable component based on the combined flux within the first DAC storage loop and the second DAC storage loop through an interface carried by the first DAC storage loop that communicates with the programmable component.

The method may then end until it is begun again, or the method may be repeated in an iterative manner or in parallel to program multiple programmable components.

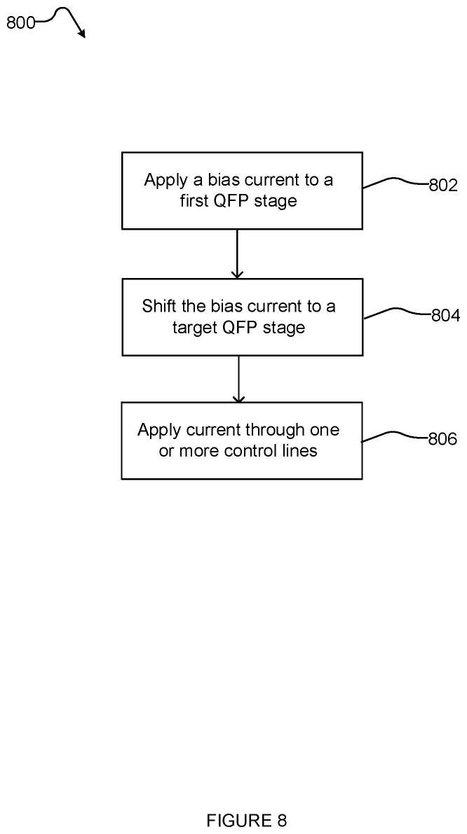

FIG. 8 is a flow chart illustrating an example method 800 for loading a pulse into a target stage of a DAC according to the present disclosure. Method 800 may be implemented by a programming system such as the system discussed with respect to FIG. 1.

Method 800 includes acts 802 to 806, though those of skill in the art will appreciate that in alternative implementations certain acts may be omitted and/or additional acts may be added. Those of skill in the art will appreciate that the illustrated order of the acts is shown for exemplary purposes only and may change in alterative implementations.

Method 800 starts, for example in response to an initiation of the programming. At 802, a bias current is applied to a first QFP stage.

At 804, the bias current is shifted to a target QFP stage through an intermediate QFP stage. In some implementations, this may include applying a flux bias to a first Josephson junction carried by the first QFP stage and applying a flux bias to an intermediate Josephson junction carried by the intermediate QFP stage, and then suppressing the first Josephson junction of the first QFP stage such that the state of the first QFP stage is transferred to the intermediate QFP stage. A pulse may be loaded into the target DAC storage loop via the target QFP stage by then applying a flux bias to a target Josephson junction of the target QFP stage in order to copy the state of the intermediate QFP stage into the target QFP stage.

At 806, current is applied through one or more control lines to transfer flux into a target DAC storage loop. In some implementations, this may include introducing a current to a first control line in communication with the target DAC storage loop and introducing a current to a second control line in communication with the DAC Josephson junction to increase the current through the DAC Josephson junction over a threshold to cause the bias current to transfer from the target QFP stage into a galvanically coupled target DAC storage loop. The current may then be removed from the first and second control lines, and the flux bias of the target QFP stage may be suppressed. As the state remains in the intermediate QFP stage, these acts may be repeated to iteratively load pulses into the target DAC storage loop via the target QFP stage until an intended number of pulses have been introduced into the target DAC storage loop.

The method may then end until it is begun again, or the method may be repeated in an iterative manner or in parallel to load multiple DAC storage loops.

In some implementations, the reverse in direction that occurs when transferring a pulse between QFP stages results in the need for an odd number greater than one (e.g., three) of QFP stages in line to transmit a state to a target QFP stage. The first QFP stage receives the state intended for the target QFP stage, and transfers it to the intermediate QFP stage, where it is in the reverse direction. The intermediate QFP stage then transfers the state to the target QFP stage, where it is returned to the original direction. In this manner, an array of QFP stages can be used to program one-third of the DAC storage loops for each programming act. This may beneficially allow for parallel programming of a large number of DAC storage loops within a quantum processor. Additionally, in some implementations, QFP states may be preloaded into a shift register that is in communication with the array of QFP stages and DAC storage loops.

Referring to FIG. 6A, one implementation of method 800 where pulses are loaded into the third stage of DAC 602 will be discussed. A bias is applied to first QFP stage 622 through flux bias line 650 to introduce a current in QFP loop 622. It will be understood that this bias may also be applied by a stage in a QFP shift register, or through another connected QFP stage of a DAC. A signal is introduced to Josephson junction annealing line 652a, and then Josephson junction annealing line 652b, after which the signal to line 652a is suppressed or set to zero. This causes the current introduced in first QFP loop 622 to be transferred into second QFP loop 624. It will be understood that the direction of the current may be reversed during the transfer. A signal is then introduced to Josephson junction annealing line 652c, resulting in the current being introduced to third QFP loop 638 in the direction of the original signal. To then introduce a pulse to DAC storage loop 630, control line 620 and control line 654c are turned ON to overcome the threshold of JJ 634. Control lines 620 and 654c can then be turned OFF, and annealing line 652c can be suppressed. In order to introduce another pulse, signal may again be introduced to annealing line 652c and control lines 620 and 654c can again be turned ON. This act may be repeated until the intended number of pulses have been loaded. In some implementations loading DAC storage loop 630 destroys the state held in QFP loop 638 and thus is copied from QFP loop 624 for each state loaded into DAC storage loop 630.

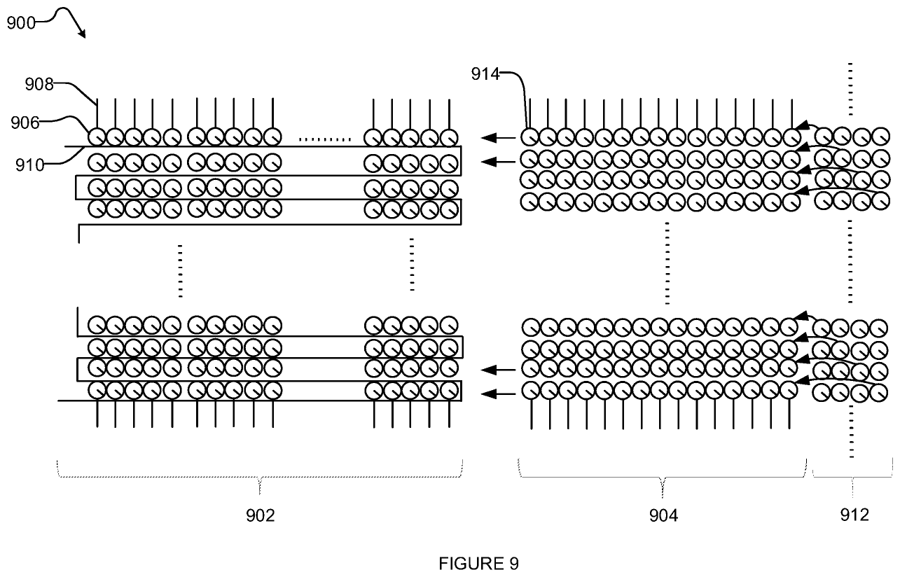

Referring to FIG. 9, a representation of an example implementation of a quantum processor 900 with an array of DACs 902 programmed by a QFP shift register 904 (also referred to herein as a memory array) will be discussed. Each QFP-DAC component 906 is represented by a circle (only one called out for clarity) within array of DACs 902, the QFP-DAC components are described herein. Power lines 908 are in communication with QFP-DAC components, and a global signal line 910 passes through the array of DACs 902. It will be understood that different numbers of QFP-DACs 906 with different numbers of stages may be used in some implementations. In the example implementation of FIG. 9, four stage QFP-DACs 906 are shown. Data may be transmitted through data path 912 into memory array 904, where the data is passed horizontally through QFP stages 914 of a QFP shift register into array of QFP-DACs 902. Once the QFP stages of the QFP-DACs 906 receive the data, power lines 908 and global signal line 910 may be raised, and flux passed into the selected DAC stages in order to program the QFP-DACs 906. This process may be repeated until all DACs have been programmed. Flux may then be transmitted to programmable components within the quantum processor to program those components using the QFP-DACs 906. While QFP stages 914 and QFP-DACs 906 are shown using similar circles, it will be understood that QFP shift register 904 acts as memory and transmits data horizontally into array of DACs 902. Array of DACs 902 does not contain separate QFP components to transmit data. Instead, array of DACs 902 contains QFP-DACs 906 as described herein, which may beneficially allow data to be transmitted through QFP stages of QFP-DACs 906 and also allow for programming into the storage loop stage of QFP-DACs 906 based on the data contained in the QFP stage of QFP-DACs 906. In some implementations QFP-DACs may be programmed without requiring individual combinations of outside signal lines to address each DAC. QFP-DACs may also beneficially be programmed in parallel, such as by addressing ⅓ of the DAC storage loops with each programming act.

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for exemplary purposes only and may change in alternative examples. Some of the exemplary acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the exemplary methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. patent application Ser. Nos. 16/098,801; 63/136,987; U.S. Pat. Nos. 7,135,701; 7,418,283; 7,533,068; 7,876,248; 8,008,942; 8,098,179; 8,195,596; 8,190,548; 8,421,053; 10,528,886, and PCT Patent Publication No. WO2012064974.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A digital to analog converter (DAC) comprising:
a first stage comprising a first storage loop interrupted by a first Josephson junction, the first storage loop having an interface operable to communicate with an external component;
a second stage comprising a second storage loop interrupted by a second Josephson junction, the second storage loop galvanically coupled to the first storage loop, the first Josephson junction and the second Josephson junction coupled in series to a first control line; and
a first quantum flux parametron (QFP) loop and a second quantum QFP loop, the first and the second QFP loops galvanically coupled to and extending from a respective one of the first stage and the second stage.

2. The DAC of claim 1, further comprising:
a third stage galvanically coupled to the second stage and a fourth stage galvanically coupled to the third stage, the third and fourth stages comprising a third storage loop and a fourth storage loop, the third and the fourth storage loops interrupted by a third Josephson junction and a fourth Josephson junction respectively, the third and the fourth Josephson junctions being coupled in series to the first control line; and
a third QFP loop and a fourth QFP loop, the third and the fourth QFP loops galvanically coupled to and extending from a respective one of the third stage and the fourth stage.

3. The DAC of claim 1, wherein each QFP loop comprises a respective Josephson junction.

4. The DAC of claim 3, wherein the respective Josephson junction of each QFP loop comprises a respective compound Josephson junction.

5. The DAC of claim 1, wherein the first and second Josephson junctions each comprise a compound Josephson junction.

6. The DAC of claim 1, wherein the first and the second QFP loops are symmetrically connected to the respective one of the first stage and the second stage, and wherein the first QFP loop is isolated from the second QFP loop.

7. The DAC of claim 6, wherein:
the first control line bisects each of the first storage loop and the second storage loop;
each of the first storage loop and the second storage loop comprise a respective Josephson junction on each of a respective first side and a respective second side of each storage loop; and
each of the first and the second QFP loops are coupled to extend from the respective first side of the respective storage loop to the respective second side of the respective storage loop.

8. The DAC of claim 6, wherein each of the first and the second QFP loops are galvanically coupled to one or more additional QFP loops.

9. The DAC of claim 1, further comprising a second control line extending at least approximately perpendicularly to the first control line, wherein the second control line is positioned to be inductively coupled to each of the first storage loop and the second storage loop.

10. The DAC of claim 1, wherein the first and the second QFP loops are galvanically coupled along the first control line.

11. The DAC of claim 2, wherein the first, the second, the third, and the fourth QFP loops are galvanically coupled along the first control line.

12. The DAC of claim 10, further comprising a flux bias line communicatively coupleable to the first QFP loop.

13. The DAC of claim 12, wherein the flux bias line comprises a QFP stage of a QFP shift register.

14. The DAC of claim 12, wherein the flux bias line comprises a signal line.

15.-19. (canceled)

20. A quantum processor comprising:
one or more programmable superconducting components;
a shift register comprising two or more rows extending in a first direction and formed from a plurality of quantum flux parametron (QFP) based shift register stages, each QFP based shift register stage within a respective row coupled to at least one other QFP based shift register stage of the plurality of QFP based shift register stages;
a respective digital to analog converter quantum flux parametron (DAC-QFP) coupled to one QFP based shift register stage of each row in the shift register;
a respective digital to analog converter (DAC) storage loop galvanically coupled to each DAC-QFP by a galvanic coupler, the galvanic coupler including a Josephson junction;
each of the respective DAC storage loops being galvanically coupled along a second direction perpendicular to the first direction; and
one of the respective DAC storage loops being in communication with one of the one or more programmable superconducting components.

21. The quantum processor of claim 20, wherein the DAC-QFPs are arranged in an array.

22. The quantum processor of claim 20, wherein a power line extends in the second direction between QFPs in a column extending along the first direction.

23. The quantum processor of claim 22, wherein a global signal line extends perpendicular to the power line in the first direction and along a first row of QFPs.

24. The quantum processor of claim 20, wherein the DAC storage loop comprises a compound Josephson junction (CJJ) and the DAC-QFP is galvanically coupled symmetrically to either side of the CJJ.

25. (canceled)

26. (canceled)

27. The quantum processor of claim 20, wherein at least one of the one or more programmable superconducting components comprises a superconducting qubit.
